(19) United States
(12) Patent Application Publication
(10) Pub. No.: US 2025/0054735 A1
(43) Pub. Date: Feb. 13, 2025

(54) EDGE RING AND APPARATUS FOR PROCESSING A SUBSTRATE INCLUDING THE SAME

(71) Applicant: SAMSUNG ELECTRONICS CO., LTD., Suwon-si (KR)

(72) Inventors: Wookhyeon Kwon, Suwon-si (KR); Minnhoo Choi, Suwon-si (KR); Songyun Kang, Suwon-si (KR); Yongwoo Kim, Suwon-si (KR); Jaehyun Kim, Suwon-si (KR); Hansol Kim, Suwon-si (KR); Chulwoo Park, Suwon-si (KR); Jaehyun Soh, Suwon-si (KR); Dongkyu Shin, Suwon-si (KR); Deukho Lee, Suwon-si (KR); Hoontaek Lee, Suwon-si (KR); Junghyun Cho, Suwon-si (KR); Yangyeon Chu, Suwon-si (KR); Kaan Uzun, Suwon-si (KR)

(21) Appl. No.: 18/595,009

(22) Filed: Mar. 4, 2024

(30) Foreign Application Priority Data
Aug. 9, 2023 (KR) 10-2023-0103974

(51) Int. Cl. H01J 37/32

(52) U.S. Cl. CPC H01J 37/32642; H01J 37/32559

(57) ABSTRACT

A system is described for protecting the edge region of a substrate during a plasma process. The system includes an outer ring with a plurality of outer uneven portions and an inner ring also with a plurality of inner uneven portions. The outer ring covers the edge region of the substrate. The inner ring may rotate around the center point of the outer ring. When the inner ring is rotated, each of the inner uneven portions and each the outer uneven portions may slide by each other to overlap and to form openings. Changes of the opening ratios in the gaps (or the overlap ratios of the inner and outer uneven portions) may change a thickness of a plasma sheath. Thus, the plasma sheath in an edge region of the substrate may be readily controlled.

### CROSS-RELATED APPLICATION

This application claims priority under 35 USC § 119 to Korean Patent Application No. 10-2023-0103974, filed on Aug. 9, 2023, in the Korean Intellectual Property Office (KIPO), the contents of which are herein incorporated by reference in their entirety.

### BACKGROUND

Generally, an apparatus for processing a substrate may form a layer on the substrate or etch a layer on the substrate using the plasma. The apparatus may include an edge ring configured to concentrate plasma on the substrate.

According to related arts, a plasma sheath may be formed along surfaces of the substrate and the edge ring. In an etching process, a shape of the plasma sheath formed in an edge region of the substrate may be affected by the edge ring. However, after installing the edge ring at the apparatus, the shape of the edge ring cannot be changed. Thus, it may be difficult to control the plasma sheath in the edge region of the substrate.

Further, byproducts may be accumulated on the edge ring. Because the edge ring may not be easily controlled, the byproducts on the edge ring may not be discharged from the apparatus. As a result, the substrate may be contaminated by the byproducts.

### SUMMARY

An edge ring is presented that may be capable of easily controlling a plasma sheath in an edge region of a substrate.

Example implementations also cover an apparatus for processing a substrate including the above-mentioned edge ring.

In some implementations, an edge ring includes an outer ring, an inner ring, a plurality of outer uneven portions and a plurality of inner uneven portions. The outer ring may cover an edge region of a substrate processed by a plasma. The inner ring may be rotatably arranged in the outer ring around a center point of the outer ring. The outer uneven portions may be provided to the outer ring. The inner uneven portions may be provided to the inner ring. The inner uneven portions may be rotated together with the inner ring.

In some implementations, an edge ring includes an outer ring, an inner ring, a supporting ring and a rotation module. The outer ring may cover an edge region of a substrate processed by plasma. A plurality of outer uneven portions may be formed on an upper surface of the outer ring. The inner ring may be rotatably arranged in the outer ring around a center point of the outer ring. A plurality of outer uneven portions may be formed on an upper surface of the inner ring. The supporting ring may be arranged under the inner ring to rotatably support the inner ring. The rotation module may be provided to the supporting ring and the inner ring to rotate the inner ring around the center point of the outer ring.

In some implementations, an edge ring includes an outer ring configured to cover an edge region of a substrate processed by a plasma, the outer ring including a plurality of uneven portions formed on an upper surface of the outer ring; an inner ring rotatably arranged in the outer ring around a center point of the outer ring, the inner ring including a plurality of uneven portions formed on an upper surface of the inner ring; a supporting ring arranged under the inner ring to rotatably support the inner ring; and a rotating module to rotate the inner ring about the center point of the outer ring, Each of the plurality of inner uneven portions and each of the plurality of outer uneven portions form a plurality of openings corresponding to an overlap between the inner uneven portion and the outer uneven portion in a radial line of the outer ring in accordance with rotation angles of the inner ring to control a plasma sheath. The outer uneven portions are arranged on an upper surface of the outer ring along a circumferential direction of the outer ring and separated by a plurality of first gaps, the inner uneven portions are arranged on an upper surface of the inner ring along a circumferential direction of the inner ring by a plurality of second gaps narrower than the first gaps, and each of the inner uneven portions has a width of no more than the first gap. The rotation module comprises a plurality of upper sawteeth formed on a lower surface of the inner ring, each of the upper sawteeth including a slanted surface; a plurality of lower sawteeth formed on an upper surface of the supporting ring, each of the lower sawteeth selectively engaged with two adjacent upper sawteeth of the plurality of upper sawteeth; and a lift pin vertically movable in the supporting ring, the lift pin including a slanted contact surface slidably making contact with at least one slanted surface of the plurality of upper sawteeth to lift and rotate the inner ring.

In some implementations, an apparatus for processing a substrate is provided, in which the apparatus includes a reaction chamber, an electrostatic chuck (ESC), a plasma generator and an edge ring. The reaction chamber may receive the substrate. The ESC may be arranged in the reaction chamber to support the substrate. The plasma generator may generate plasma in the reaction chamber from a reaction gas. The edge ring may cover the edge region of the substrate on the ESC. The edge ring may include an outer ring, an inner ring, a plurality of outer uneven portions and a plurality of inner uneven portions. The outer ring may cover the edge region of the substrate. The inner ring may be rotatably arranged in the outer ring around a center point of the outer ring. The outer uneven portions may be provided to the outer ring. The inner uneven portions may be provided to the inner ring. The inner uneven portions may be rotated together with the inner ring.

In some implementations, the inner ring may be selectively rotated around the center point of the outer ring. Thus, each of the inner uneven portions and the outer uneven portions may selectively form a plurality of opening ratios, which may correspond to an overlap ratio between the inner uneven portion and the outer uneven portion along a radial line of the outer ring, in accordance with rotation angles of the inner ring. Changes of the opening ratios may change a thickness of a plasma sheath. Thus, the plasma sheath in an edge region of the substrate may be readily controlled.

Further, byproducts may be easily discharged from the reaction chamber by setting a high opening ratio. Thus, a contamination of the substrate by the byproducts may be suppressed.

### BRIEF DESCRIPTION OF THE DRAWINGS

Example implementations will be more clearly understood from the following detailed description taken in conjunction with the accompanying drawings. FIGS. 1 to 20 represent non-limiting, example implementations as described herein.

FIG. 1 is a cross-sectional view illustrating an example of an apparatus for processing a substrate;

FIG. 2 is a perspective view illustrating an example of an edge ring of the apparatus in FIG. 1;

FIG. 3 is an enlarged front view illustrating an outer ring of the edge ring in FIG. 2;

FIG. 4 is an enlarged front view illustrating an inner ring of the edge ring in FIG. 2;

FIG. 5 is a plan view illustrating an inner ring and an outer ring of the edge ring in FIG. 2;

FIGS. 6 and 7 are perspective views illustrating a rotation module of the edge ring in FIG. 2;

FIG. 8 is a cross-sectional view illustrating the rotation module in FIG. 6;

FIGS. 9 to 13 are cross-sectional views illustrating an example operation of the rotation module in FIG. 6;

FIGS. 14 to 19 are plan views and cross-sectional views illustrating changes of opening ratios in the edge ring of FIG. 2; and

FIG. 20 is a cross-sectional view illustrating an apparatus for processing a substrate.

### DETAILED DESCRIPTION

Hereinafter, example implementations will be explained in detail with reference to the accompanying drawings.

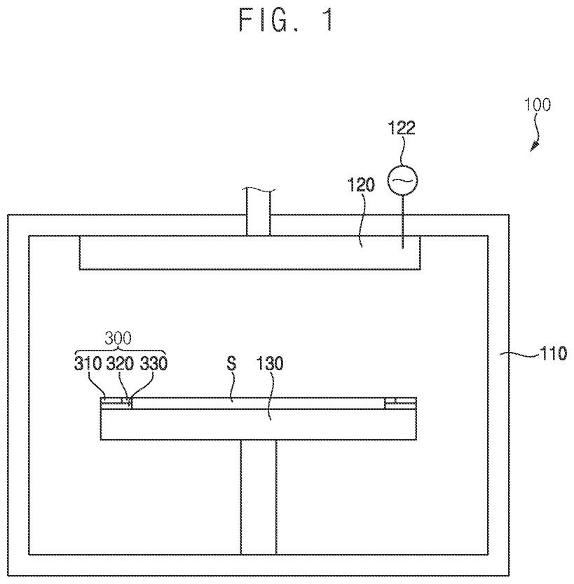

FIG. 1 is a cross-sectional view illustrating an apparatus for processing a substrate.

Referring to FIG. 1, a capacitively coupled plasma (CCP) type apparatus 100 for processing a substrate may apply an RF power to opposite electrodes to generate plasma from a reaction gas using an RF electric field between the electrodes. The CCP type apparatus 100 may include semiconductor fabrication apparatuses configured to process the substrate S using the plasma in a reaction chamber such as a deposition apparatus, an etching apparatus, an ashing apparatus, etc.

The CCP type apparatus 100 may include a reaction chamber 110, a showerhead 120, an electrostatic chuck (ESC) 130, an edge 300, etc. That is, the CCP type apparatus 100 may include the showerhead 120 as part of the plasma generator.

The reaction chamber 110 may have an internal space configured to receive the substrate such as a semiconductor substrate S. The reaction chamber 110 may include a vacuum region configured to define a space where the plasma may be formed from a reaction gas.

The showerhead 120 may be arranged at an upper region in the reaction chamber 110. The showerhead 120 may include a plurality of injection holes configured to inject the reaction gas into the reaction chamber 110. An RF power supply 122 may be connected to the showerhead 120. Thus, the showerhead 120 may function as an upper electrode.

The ESC 130 may be arranged at a lower region in the reaction chamber 110. An RF power supply may be connected to the ESC 130. Thus, the ESC 130 may function as a lower electrode. A matching circuit may be arranged between the RF power supply and the ESC 130. A plurality of lift holes may be vertically formed through the ESC 130.

Additionally, a plurality of substrate lift pins may be movably inserted into the lift holes of the ESC 130. The substrate lift pins may support the semiconductor substrate S. The substrate lift pins may be downwardly moved to place the semiconductor substrate S on an upper surface of the ESC 130. The substrate lift pins may be upwardly moved with the semiconductor substrate S on which a plasma process may be performed.

The edge ring 300 may be arranged at an edge portion of the ESC 130 to cover an edge region of the semiconductor substrate S. The edge ring 300 may protect an outer circumferential surface of the semiconductor substrate S from the plasma. Further, the edge ring 300 may concentrate the plasma on an upper surface of the semiconductor substrate S.

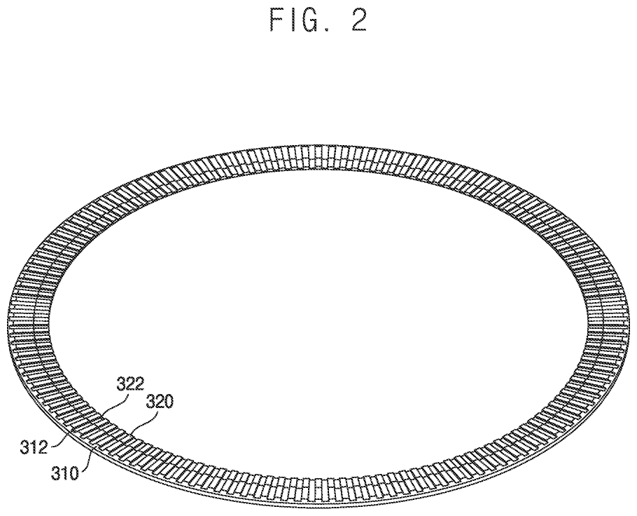

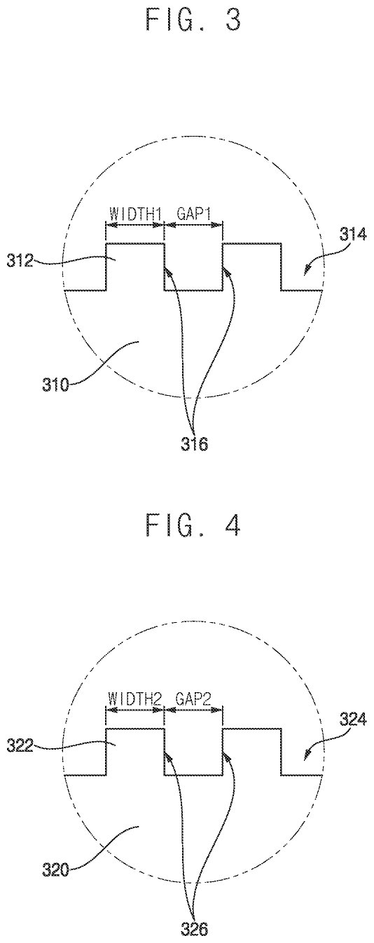

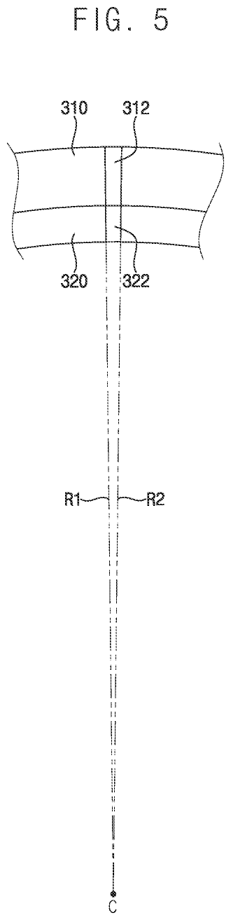

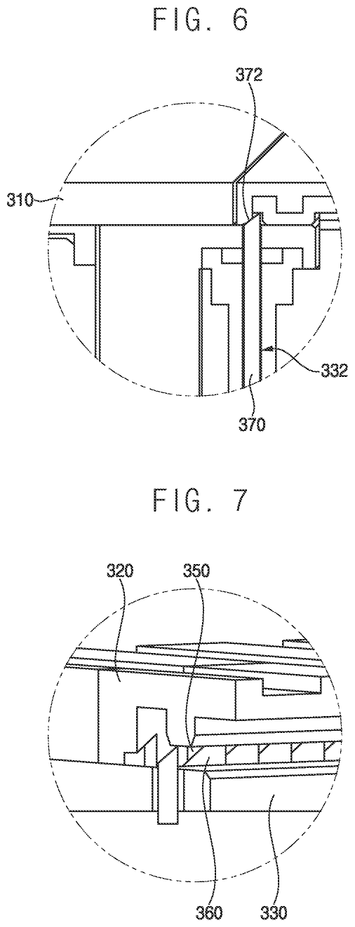

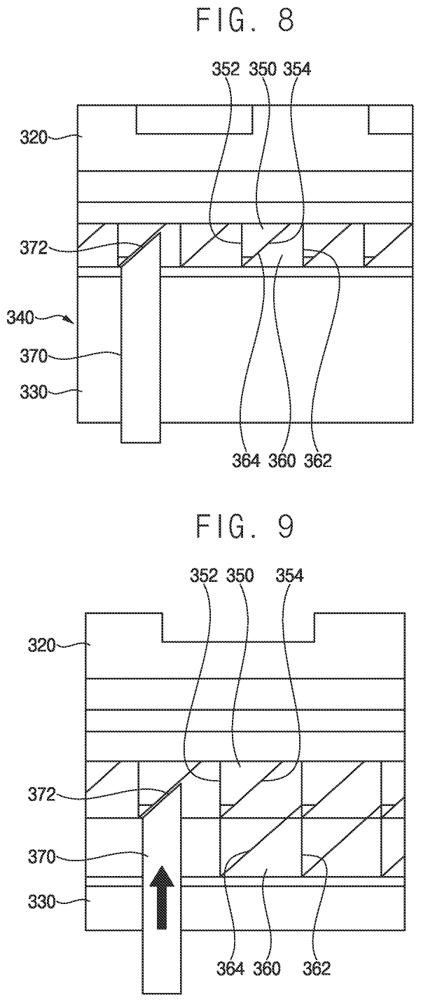

FIG. 2 is a perspective view illustrating an edge ring of the apparatus in FIG. 1, FIG. 3 is an enlarged front view illustrating an outer ring of the edge ring in FIG. 2, FIG. 4 is an enlarged front view illustrating an inner ring of the edge ring in FIG. 2, FIG. 5 is a plan view illustrating an inner ring and an outer ring of the edge ring in FIG. 2, FIGS. 6 and 7 are perspective views illustrating a rotation module of the edge ring in FIG. 2 and FIG. 8 is a cross-sectional view illustrating the rotation module in FIG. 6.

Referring to FIGS. 2 to 8, the edge ring 300 may include an outer ring 310, an inner ring 320, a plurality of outer uneven portions 312, a plurality of inner uneven portions 322, a supporting ring 330 and a rotation module 340.

The outer ring 310 may cover the edge region of the semiconductor substrate S on the upper surface of the ESC 130. The outer uneven portions 312 may be provided to the outer ring 310. The outer uneven portions 312 may be arranged on an upper surface 314 of the outer ring 310, but not limited thereto. Further, the outer uneven portion 312 may be arranged on the upper surface 314 of the outer ring 310 in a circumferential direction of the outer ring 310. The outer uneven portions 312 may be spaced apart from each other by a uniform first gap. The outer uneven portions 312 may be integrally formed with the outer ring 310, but not limited thereto. For example, the outer uneven portions 312 may be parts separated from the upper surface 314 of the outer ring 310.

The inner ring 320 may be arranged in the outer ring 310. Thus, the inner ring 320 may have two radii shorter than either of the two radii of the outer ring 310. Particularly, the inner ring 320 may be rotated around the center point of the outer ring 310.

The inner uneven portions 322 may be arranged on an upper surface 324 of the inner ring 320. The inner uneven portions 322 may be arranged on the upper surface 324 of the inner ring 320 along a circumferential direction of the inner ring 320. The inner uneven portions 322 may be spaced apart from each other by a uniform second gap narrower than the first gap. The inner uneven portions 322 may be integrally formed with the inner ring 320, but not limited thereto. For example, the inner uneven portions 322 may be parts separated from the upper surface 324 of the inner ring 320.

In example implementations, each of the side surfaces of the outer uneven portions 312 and each of the side surfaces of the inner uneven portions 322 may each define two adjacent radii R1 and R2 among the radii of the outer ring 310, as shown in FIG. 5. That is, the outer uneven portion 312 and the inner uneven portion 322 adjacent to the outer uneven portion 312 may be arranged radially with respect to the center point of the outer ring 310.

In example implementations, each of the outer uneven portions 312 may have a rectangular parallelepiped shape, which includes shapes with nearly parallel faces or nearly rectangular parallelepipeds. Thus, the outer uneven portion 312 may have a rectangular cross-sectional shape, but is not limited thereto. For example, the outer uneven portion 312 may have a triangular cross-sectional shape, a circular cross-sectional shape, an elliptical cross-sectional shape, etc. Each of the inner uneven portions 322 may have a shape corresponding to the shape of the outer uneven portion 312. Thus, the inner uneven portion 322 may have a rectangular parallelepiped shape smaller than the rectangular parallelepiped shape of the outer uneven portion 312, but not limited thereto. For example, the inner uneven portion 322 may have a triangular cross-sectional shape, a circular cross-sectional shape, an elliptical cross-sectional shape, etc.

When the outer uneven portion 312 and the inner uneven portion 322 have the rectangular parallelepiped shapes, the outer uneven portion 312 and the inner uneven portion 322 have upper surfaces 314 and 324 which are substantially coplanar with each other. The outer uneven portion 312 and the inner uneven portion 322 may have both side surfaces 316 and 326 on vertical planes formed by each of the two radial lines R1 and R2 with the vertical direction.

As mentioned above, because the inner ring 320 may be rotated about the center point of the outer ring 310, the inner uneven portion 322 and the outer uneven portion 312 may overlap in the radial direction of the outer ring 310. Thus an overlapping ratio between the uneven portions may be changed by the rotation of the inner ring 320 relative to the outer ring 310. The overlapping ratio between the inner uneven portion 322 and the outer uneven portion 312 may correspond to an opening ratio of the gaps between the uneven portions. The overlapping ratio of the uneven portions may correspond with a ratio of an exposed inner side surface of the outer uneven portion 312 to the inner side surface of the outer uneven portion 312 by the inner uneven portion 322. Because the inner ring 320 may have a plurality of rotation angles, the opening ratio of the outer uneven portion 312 with respect to the inner uneven portion 322 may have a plurality of values. That is, the inner uneven portion 322 and the outer uneven portion 312 may be set to a selective opening ratio in accordance with a selected rotation angle of the inner ring 320.

Further, the first gap between the outer uneven portions 312 may be no less than a width of the inner uneven portion 322. (Gap1≥Width2, from FIG. 3 and FIG. 4.) Thus, when the inner uneven portion 322 may be arranged between the outer uneven portions 312, the entire outer uneven portion 312 may be exposed. That is, the opening ratio between the inner uneven portion 322 and the outer uneven portion 312 may be about 100%.

A plasma sheath may be formed along surfaces of the semiconductor substrate S and the edge ring 300. Thus, when the opening ratio between the outer uneven portion 312 and the inner uneven portion 322 may be changed, a thickness of the plasma sheath may also be changed. Therefore, the plasma sheath in an edge region of the semiconductor substrate S may be readily controlled by controlling the opening ratio between the out uneven portion 312 and the inner uneven portion 322.

The supporting ring 330 may be arranged under both the outer ring 310 and the inner ring 320. The supporting ring 330 may rotatably support the inner ring 320. Further, the supporting ring 330 may fix the outer ring 310. The supporting ring 330 may include a lift hole 332 formed in a vertical direction. The lift hole 332 may be exposed through an upper surface of the supporting ring 330.

The rotation module 340 may be provided to the inner ring 320 and the supporting ring 330. The rotation module 340 may rotate the inner ring 320 around the center point of the outer ring 310. In an example, the rotation module 340 may include a plurality of upper sawteeth 350, a plurality of lower sawteeth 360 and a lift pin 370.

In an implementation, the upper sawteeth 350 may be formed on a lower surface of the inner ring 320. Each of the upper sawteeth 350 may have a right-angled triangle formed from the lower surface of the inner ring 320 toward an upper surface of the supporting ring 330. Thus, each upper sawtooth 350 may have a vertical surface 352 and a slanted surface 354. The vertical surface 352 may be vertically extended from the lower surface of the inner ring 320 toward the upper surface of the supporting ring 330. The slanted surface 354 may extend at a slant from a lower end of the vertical surface 352 to the lower surface of the inner ring 320. An angle of the slanted surface 354 may be about 45°, but not limited thereto.

The lower sawteeth 360 may be formed on an upper surface of the supporting ring 330. The lower sawteeth 360 may be engaged with the upper sawteeth 350. That is, the lower sawteeth 360 may be inserted into spaces between the upper sawteeth 350. Thus, each of the lower sawteeth 360 may have a size and a shape corresponding to a size and a shape of the upper sawtooth 350. Because the upper sawtooth 350 may have a right-angle triangle, the lower sawtooth 360 may also have a right-angle triangle. In particular, the lower sawtooth 360 may have a vertical surface 362 and a slanted surface 364. The vertical surface 362 may be vertically extended from the upper surface of the supporting ring 330 toward the lower surface of the inner ring 320. The slanted surface 364 may extend at a slant from an upper end of the vertical surface 362 to the upper surface of the supporting ring 330. The slanted surface 364 of the lower sawtooth 360 may have an angle substantially the same as the angle of the slanted surface 354 of the upper sawtooth 350.

Therefore, when the upper sawteeth 350 may be engaged with the lower sawteeth 360, the vertical surface 352 of the upper sawtooth 350 may make contact with the vertical surface 362 of the lower sawtooth 360. Further, the slanted surface 354 of the upper sawtooth 350 may also make contact with the slanted surface 364 of the lower sawtooth 360.

The lift pin 370 may be movably arranged in the lift hole 332 of the supporting ring 330 in the vertical direction. The lift pin 370 may include a slanted contact surface 372. The slanted contact surface 372 may be formed on an upper end of the lift pin 370. The slanted contact surface 372 may slidably make contact with the slanted surface 354 of the upper sawtooth 350. Further, the lift pin 370 may have a width narrower than a width of the upper sawtooth 350. Thus, a gap may be formed between the lift pin 370 and the vertical surface 352 of the upper sawtooth 350.

Therefore, when the lift pin 370 is moved upward, the slanted contact surface 372 may slidably make contact with the slanted surface 354 of a selected upper sawtooth 350 to raise the inner ring 320. When the lift pin 370 arrives at a maximum height, the slanted surface 354 of a selected upper sawtooth 350, including sawteeth adjacent to the selected upper sawtooth 350 making contact with the lift pin 370, may pass by the upper end of the lower sawteeth 360 and may then be positioned on the slanted surface 364 of the lower sawtooth 360. When the lift pin 370 is moved downward, the slanted surface 354 of the adjacent upper sawteeth 350 may also be downwardly moved along the slanted surface 364 of the lower sawteeth 360. Because the upper sawtooth 350 may be moved by a small distance, the inner ring 320 may also be rotated by a small angle together with the small distance moved by the upper sawtooth 350. That is, the upper sawtooth 350 inserted into the space between the lower sawteeth 360 may be moved to another space between the adjacent lower sawteeth 360 by the lifting motion of the lift pin 370 so that the inner ring 320 may be rotated. Thus, the opening ratio between the inner uneven portion 322 and the outer uneven portion 312 may be changed by the rotation module which causes a rotation of the inner ring 320.

FIGS. 9 to 13 are cross-sectional views illustrating an operation of the rotation module in FIG. 6.

Referring to FIG. 9, the upper sawteeth 350 may be engaged with the lower sawteeth 360. The lift pin 370 may be downwardly moved in the lift hole 332. For example, a first upper sawtooth 350 among the upper sawteeth 350 may be inserted between first and second lower sawteeth 360.

When the lift pin 370 is moved upwards, the slanted contact surface 372 may make contact with the slanted surface 354 of the second upper sawtooth 350 over the lift pin 370. The slanted contact surface 372 may move the slanted surface 354 of the second upper sawtooth 350 upwards. Thus, the vertical surface 352 of the first upper sawtooth 350 may be upwardly moved along the vertical surface 362 of the first lower sawtooth 360.

Referring to FIG. 10, the lift pin 370 may upwardly move the second upper sawtooth 350 until the lower end of the first upper sawtooth 350 may make contact with the upper end of the first lower sawtooth 360.

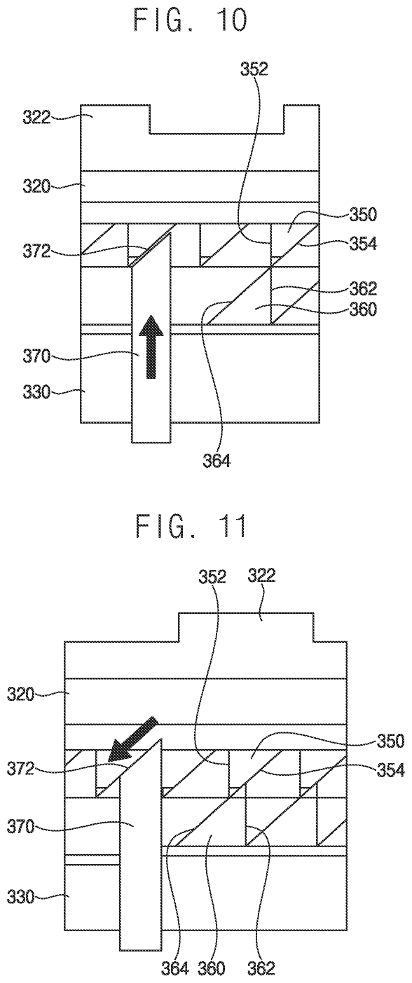

Referring to FIG. 11, when the lift pin 370 may be continuously ascended, the upper end of the slanted contact surface 372 may make contact with the upper end of the slanted surface 354 of the second upper sawtooth 350. In this case, the lower end of the first upper sawtooth 350 may cross over the upper end of the first lower sawtooth 360. Thus, the slanted surface 354 of the first upper sawtooth 350 may slidably make contact with the slanted surface 364 of the first lower sawtooth 360.

Referring to FIG. 12, when the lift pin 370 gradually descends, the slanted surface 354 of the first upper sawtooth 350 may slide on the slanted surface 364 of the first lower sawtooth 360 so that the first upper sawtooth 350 may be moved in a left direction. As a result, the first upper sawtooth 350 is rotated to the left, as the entire inner ring 320 is rotated. That is, all the upper sawteeth 350 may be rotated in the left direction so that the inner ring 320 may also be rotated together with the upper sawteeth 350 in the left direction.

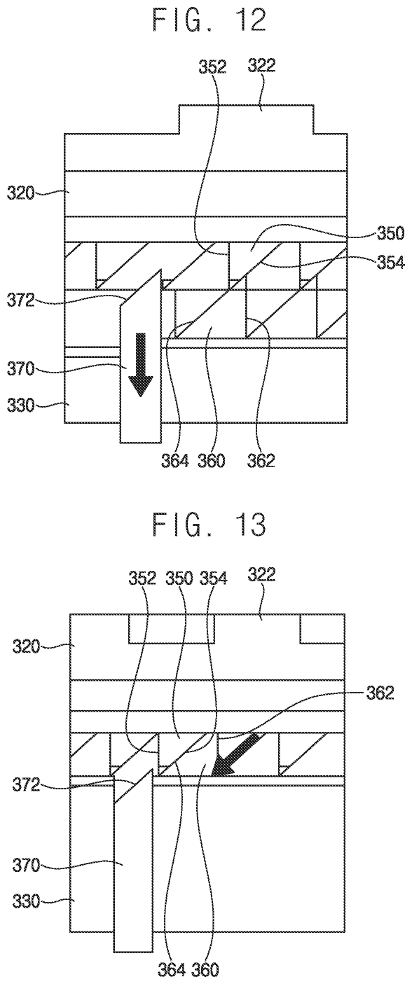

Referring to FIG. 13, when the lift pin 370 is moved down to a lowest position, each of the upper sawteeth 350 may be inserted into the spaces between the lower sawteeth 360. That is, the left rotated upper sawteeth 350 may be moved by one sawtooth step along the left direction so that the upper sawteeth 350 may be again engaged with the lower sawteeth 360.

FIGS. 14 to 19 are plan views and cross-sectional views illustrating changes of opening ratios in the edge ring of FIG. 2.

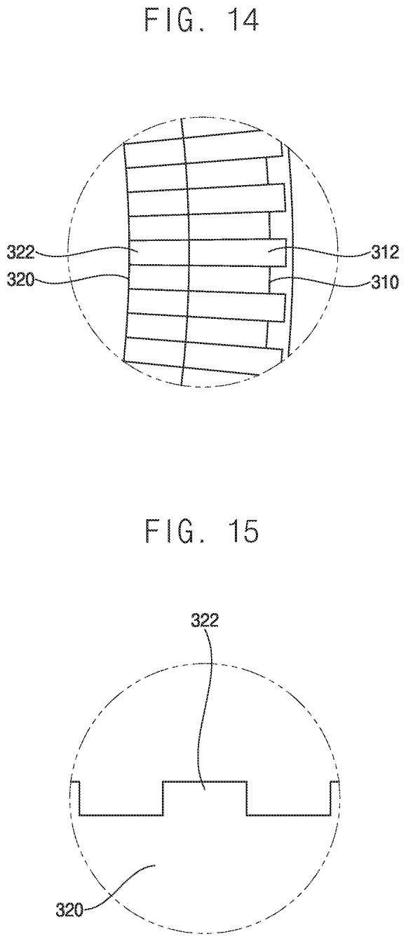

Referring to FIGS. 14 and 15, the opening ratio between the inner uneven portion 322 and the outer uneven portion 312 may be about 0%. That is, the outer uneven portion 312 may be covered by the inner uneven portion 322 so that the outer uneven portion 312 may not be exposed.

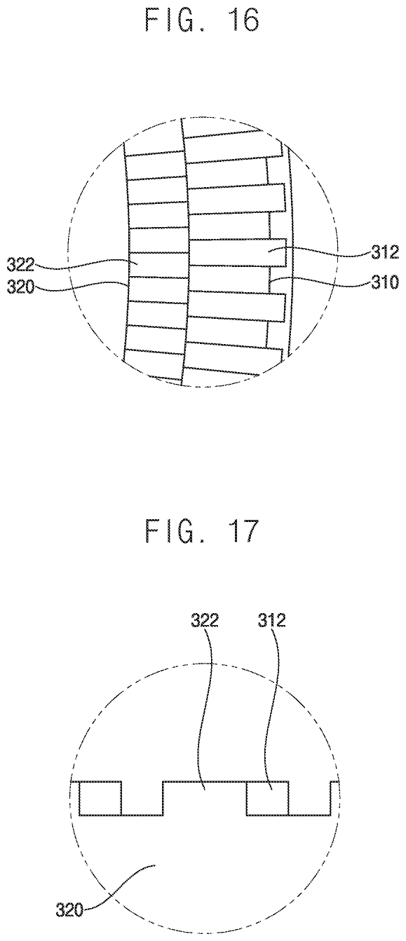

Referring to FIGS. 16 and 17, the opening ratio between the inner uneven portion 322 and the outer uneven portion 312 may be about 50%. That is, the rotating module 340 may rotate the inner ring 320 to overlap the inner uneven portion 322 with a half of the outer uneven portion 312. Thus, the overlapping ratio of the outer uneven portion 312 with respect to the inner uneven portion 322 may be about 50%.

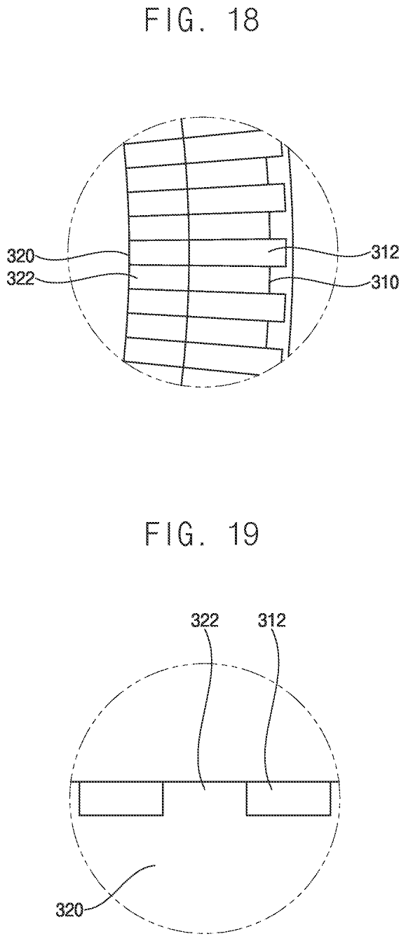

Referring to FIGS. 18 and 19, the opening ratio between the inner uneven portion 322 and the outer uneven portion 312 may be about 100%. That is, the rotating module 340 may rotate the inner ring 320 to position the inner uneven portion 322 between the outer uneven portions 312. Thus, the outer uneven portion 312 may not be overlapped with the inner uneven portion 322 so that the overlapping ratio of the outer uneven portion 312 with respect to the inner uneven portion 322 may be about 0%.

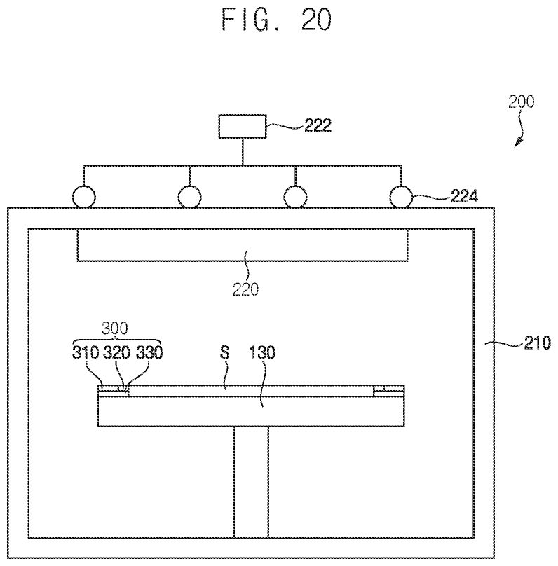

FIG. 20 is a cross-sectional view illustrating an apparatus for processing a substrate.

Referring to FIG. 20, an inductively coupled plasma (ICP) type apparatus 200 may generate plasma from a reaction gas using a magnetic field induced by, for example, a coil antenna 224. An RF power applied to the coil antenna 224 may be transmitted to the reaction gas through a dielectric window 220. The ICP type apparatus 200 may include semiconductor fabrication apparatuses configured to process the substrate S using the plasma in a reaction chamber such as a deposition apparatus, an etching apparatus, an ashing apparatus, etc.

The ICP type apparatus 200 may include a reaction chamber 210, an antenna 224, a dielectric window 220, an ESC 230, an edge ring 300, etc. That is, the ICP type apparatus 200 may include the antenna 224 and the dielectric window 220 as the plasma generator.

The reaction chamber 210 may have an internal space configured to receive the semiconductor substrate S. The reaction chamber 210 may have a vacuum region for defining a space where the plasma may be formed from the reaction gas.

The antenna 224 may be arranged on the upper surface of the reaction chamber 210. An RF power supply 222 may be connected to the antenna 224. A magnetic field induced by the antenna 224 may be applied to the reaction gas injected into the reaction chamber 210 to generate the plasma.

The dielectric window 220 may be arranged under the antenna 224. The dielectric window 220 may include a dielectric material. The dielectric window 220 may transmit the RF power from the antenna 224 into the reaction chamber 210. Further, in an example, the dielectric window 220 may inject the reaction gas into the reaction chamber 210.

The ESC 230 may be arranged at a lower region in the reaction chamber 210. An RF power supply may be connected to the ESC 230. A matching circuit may be arranged between the RF power supply and the ESC 230. A plurality of substrate lift holes may be vertically formed through the ESC 230.

Additionally, a plurality of substrate lift pins may be movably inserted into the lift holes of the ESC 230. The substrate lift pins may support the semiconductor substrate S. The substrate lift pins may be downwardly moved to place the semiconductor substrate S on an upper surface of the ESC 230. The substrate lift pins may be upwardly moved with the semiconductor substrate S on which a plasma process may be performed.

The edge ring 300 may have a structure substantially the same as the structure of the edge ring 300 in FIG. 2. Thus, any further illustrations with respect to the edge ring 300 are omitted herein for brevity.

In example implementations, the inner ring may be selectively rotated around the center point of the outer ring. Thus, each of the inner uneven portions and the outer uneven portions may selectively form a plurality of opening ratios, which may correspond to an overlap ratio between the inner uneven portion and the outer uneven portion, in accordance with rotation angles of the inner ring. Changes of the opening ratios may change a thickness of a plasma sheath. Thus, the plasma sheath in an edge region of the substrate may be readily controlled.

Further, byproducts may be easily discharged from the reaction chamber by setting a high opening ratio. Thus, a contamination of the substrate by the byproducts may be suppressed.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing description is illustrative of example implementations and is not to be construed as limiting thereof. Although a few example implementations have been described, those skilled in the art will readily appreciate that many modifications are possible in the example implementations without departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various example implementations and is not to be construed as limited to the specific examples disclosed, and that modifications to the disclosed examples, as well as other example implementations, are intended to be included within the scope of the appended claims.

What is claimed is:

1. An edge ring comprising:
an outer ring configured to cover an edge region of a substrate processed by a plasma;
an inner ring rotatably arranged inside the outer ring around a center point of the outer ring;
a plurality of outer uneven portions provided on the outer ring; and
a plurality of inner uneven portions provided on the inner ring and rotated together with the inner ring.

2. The edge ring of claim 1, wherein each of the inner uneven portions and each of the outer uneven portions form a plurality of openings corresponding to a changing overlapping ratio between the inner uneven portion and the outer uneven portion in a circumferential direction of the outer ring in accordance with a changing rotation angle of the inner ring in order to control a plasma sheath at the edge of the substrate.

3. The edge ring of claim 1, wherein the outer uneven portions are arranged on an upper surface of the outer ring along a circumferential direction of the outer ring, and the inner uneven portions are arranged on an upper surface of the inner ring along a circumferential direction of the inner ring.

4. The edge ring of claim 3, wherein the plurality of outer uneven portions are spaced apart from each other by a first gap, and each of the plurality of inner uneven portions has a width of no more than the first gap.

5. The edge ring of claim 4, wherein a left side surface and a right side surface of each of the plurality of outer uneven portions define two adjacent radii of the outer ring and each of the plurality of inner uneven portions are positioned between the two adjacent radii among radii of the outer ring.

6. The edge ring of claim 5, wherein each of the plurality of outer uneven portions has a rectangular parallelepiped shape, and each of the plurality of inner uneven portions has a rectangular parallelepiped shape smaller than the rectangular parallelepiped shape of the outer uneven portion.

7. The edge ring of claim 6, wherein each of the plurality of outer uneven portions and each of the plurality of inner uneven portions have substantially coplanar upper surfaces.

8. The edge ring of claim 6, wherein each of the plurality of the outer uneven portions and each of the plurality of the inner uneven portions have both side surfaces on vertical planes formed by the two radii.

9. The edge ring of claim 1, further comprising a supporting ring arranged under the inner ring to rotatably support the inner ring.

10. The edge ring of claim 9, further comprising a rotating module provided to the supporting ring and the inner ring to rotate the inner ring around the center point of the outer ring.

11. The edge ring of claim 10, wherein the rotation module comprises:
a plurality of upper sawteeth formed on a lower surface of the inner ring, each of the upper sawteeth including a slanted surface;
a plurality of lower sawteeth formed on an upper surface of the supporting ring and selectively engaged with the upper sawteeth; and
a lift pin vertically movable in the supporting ring, the lift pin including a slanted contact surface slidably making contact with the slanted surface of at least one of the plurality of upper saw teeth to lift and rotate the inner ring.

12. The edge ring of claim 11, wherein the lift pin has a width narrower than a width of each of the plurality of the upper sawteeth.

13. An edge ring comprising:
an outer ring configured to cover an edge region of a substrate processed by a plasma, the outer ring including a plurality of uneven portions formed on an upper surface of the outer ring;
an inner ring rotatably arranged in the outer ring around a center point of the outer ring, the inner ring including a plurality of uneven portions formed on an upper surface of the inner ring;
a supporting ring arranged under the inner ring to rotatably support the inner ring; and
a rotating module to rotate the inner ring about the center point of the outer ring,
wherein each of the plurality of inner uneven portions and each of the plurality of outer uneven portions form a plurality of openings corresponding to an overlap between the inner uneven portion and the outer uneven portion in a radial line of the outer ring in accordance with rotation angles of the inner ring to control a plasma sheath.

14. The edge ring of claim 13, wherein the outer uneven portions are arranged on an upper surface of the outer ring along a circumferential direction of the outer ring and separated by a plurality of first gaps, the inner uneven portions are arranged on an upper surface of the inner ring along a circumferential direction of the inner ring by a plurality of second gaps narrower than the first gaps, and each of the inner uneven portions has a width of no more than the first gap.

15. The edge ring of claim 14, wherein a left side surface and a right side surface of each of the outer uneven portions define two adjacent radii among radii of the outer ring and each of the inner uneven portions are positioned between two adjacent radii among radii of the outer ring.

16. The edge ring of claim 15, wherein each of the outer uneven portions has a rectangular parallelepiped shape, and each of the inner uneven portions has a rectangular parallelepiped shape smaller than the rectangular parallelepiped shape of the outer uneven portion.

17. The edge ring of claim 13, wherein the rotation module comprises:
a plurality of upper sawteeth formed on a lower surface of the inner ring, each of the upper sawteeth including a slanted surface;
a plurality of lower sawteeth formed on an upper surface of the supporting ring, each of the lower sawteeth selectively engaged with two adjacent upper sawteeth of the plurality of upper sawteeth; and
a lift pin vertically movable in the supporting ring, the lift pin including a slanted contact surface slidably making contact with at least one slanted surface of the plurality of upper sawteeth to lift and rotate the inner ring.

18. An edge ring comprising:
an outer ring configured to cover an edge region of a substrate processed by a plasma, the outer ring including a plurality of uneven portions formed on an upper surface of the outer ring;
an inner ring rotatably arranged in the outer ring around a center point of the outer ring, the inner ring including a plurality of uneven portions formed on an upper surface of the inner ring;
a supporting ring arranged under the inner ring to rotatably support the inner ring; and
a rotating module to rotate the inner ring about the center point of the outer ring,
wherein each of the plurality of inner uneven portions and each of the plurality of outer uneven portions form a plurality of openings corresponding to an overlap between the inner uneven portion and the outer uneven portion in a radial line of the outer ring in accordance with rotation angles of the inner ring to control a plasma sheath, and
wherein the outer uneven portions are arranged on an upper surface of the outer ring along a circumferential direction of the outer ring and separated by a plurality of first gaps, the inner uneven portions are arranged on an upper surface of the inner ring along a circumferential direction of the inner ring by a plurality of second gaps narrower than the first gaps, and each of the inner uneven portions has a width of no more than the first gap, and
wherein the rotation module comprises:
a plurality of upper sawteeth formed on a lower surface of the inner ring, each of the upper sawteeth including a slanted surface;
a plurality of lower sawteeth formed on an upper surface of the supporting ring, each of the lower sawteeth selectively engaged with two adjacent upper sawteeth of the plurality of upper sawteeth; and
a lift pin vertically movable in the supporting ring, the lift pin including a slanted contact surface slidably making contact with at least one slanted surface of the plurality of upper sawteeth to lift and rotate the inner ring.

19. The edge ring of claim 18, wherein a left side surface and a right side surface of each of the outer uneven portions define two adjacent radii among radii of the outer ring and each of the inner uneven portions are positioned between two adjacent radii among radii of the outer ring.

20. The edge ring of claim 19, wherein each of the outer uneven portions has a rectangular parallelepiped shape, and each of the inner uneven portions has a rectangular parallelepiped shape smaller than the rectangular parallelepiped shape of the outer uneven portion.
